(19) United States
(12) Patent Application Publication
(10) Pub. No.: US 2018/0219035 A1
(43) Pub. Date: Aug. 2, 2018

(54) SOLID STATE IMAGING DEVICE

(71) Applicant: TowerJazz Panasonic Semiconductor Co., Ltd., Uozu (JP)

(72) Inventor: Hirohisa OTSUKI, Hyogo (JP)

(21) Appl. No.: 15/940,755

(22) Filed: Mar. 29, 2018

Related U.S. Application Data
(63) Continuation of application No. PCT/JP2016/001813, filed on Mar. 29, 2016.

(30) Foreign Application Priority Data
Sep. 29, 2015 (JP) 2015-191242

(51) Int. Cl. H01L 27/146; H01L 27/148; G01S 7/486

(52) U.S. Cl. CPC H01L 27/14603; H01L 27/1463; H01L 27/14641; G01S 7/4861; H01L 27/14612; H01L 27/14812; H01L 27/14636; H01L 27/14643

(57) ABSTRACT

A plurality of pixels which are two-dimensionally arranged on a semiconductor substrate includes: a photodiode generating charge by photoelectric conversion; two readout gates each reading charge from the photodiode; and two memories each receiving the charge from the photodiode through an associated one of the two readout gates and temporarily retaining the charge received. Two of the pixels adjacent to each other in a row direction share one of the two readout gates.

### CROSS-REFERENCE TO RELATED APPLICATIONS

This is a continuation of International Application No. PCT/JP2016/001813 filed on Mar. 29, 2016, which claims priority to Japanese Patent Application No. 2015-191242 filed on Sep. 29, 2015. The entire disclosures of these applications are incorporated by reference herein.

### BACKGROUND

The present disclosure relates to a solid state imaging device that can be used for distance measurement.

Solid state imaging devices known in the art use a time of flight (TOF) technique for distance measurement. Such a solid state imaging device detects an image of light reflected from an object irradiated with pulsed light from a light emitting diode (LED), and obtains distance information based on a delay time of the reflected light with respect to the irradiation light.

Specifically, a pixel structure called a charge distribution structure, for example, is used. In this structure, a plurality of capacitors are connected to a single photodiode generating charge by photoelectric conversion. Charges are read from the photodiode at different timings in synchronization with light emission from an LED, and the read charges are separately accumulated in the capacitors. The distance to an object is calculated based on the amount of the charges accumulated in the capacitors (see Japanese Unexamined Patent Publication No. 2008-89346).

### SUMMARY

The charge distribution pixel structure known in the art requires a sufficiently large space between readout gates of adjacent pixels. This makes it difficult to reduce the pixel pitch. If an attempt is made to reduce the pixel pitch, the area of each of photodiodes and the area of each of the capacitors must be sacrificed. This imposes a significant limit on the charge amount that can be handled.

It is an object of the present disclosure to allow a solid state imaging device to have a smaller pixel pitch while being kept capable of handling a sufficiently large charge amount generated by photoelectric conversion.

According to the present disclosure, to reduce the space between readout gates of adjacent ones of pixels, such adjacent pixels share a readout gate.

A solid state imaging device according to an aspect of the present disclosure includes a plurality of pixels which are two-dimensionally arranged on a semiconductor substrate. Each of the pixels includes: a photodiode generating charge by photoelectric conversion; two readout gates each reading charge from the photodiode; and two memories each receiving the charge from the photodiode through an associated one of the two readout gates and temporarily retaining the charge received. Two of the pixels adjacent to each other in a row direction share one of the two readout gates.

According to the present disclosure, two adjacent ones of pixels share a readout gate. Thus, the space between readout gates of such adjacent pixels is reduced. This allows a solid state imaging device to have a smaller pixel pitch while being kept capable of handling a sufficiently large charge amount generated by photoelectric conversion.

### BRIEF DESCRIPTION OF THE DRAWINGS

FIG. 1 is a plan view showing structures of two pixels adjacent to each other in a solid state imaging device according to a first embodiment of the present disclosure.

FIG. 2 is a circuit diagram of the two pixels of the solid state imaging device shown in FIG. 1.

FIG. 3 is a timing diagram for explaining the principle of how the solid state imaging device shown in FIG. 1 measures the distance to an object.

FIG. 4 is a timing diagram for explaining how the solid state imaging device shown in FIG. 1 operates.

FIG. 5 is a plan view of a solid state imaging device according to a second embodiment of the present disclosure.

### DETAILED DESCRIPTION

### First Embodiment

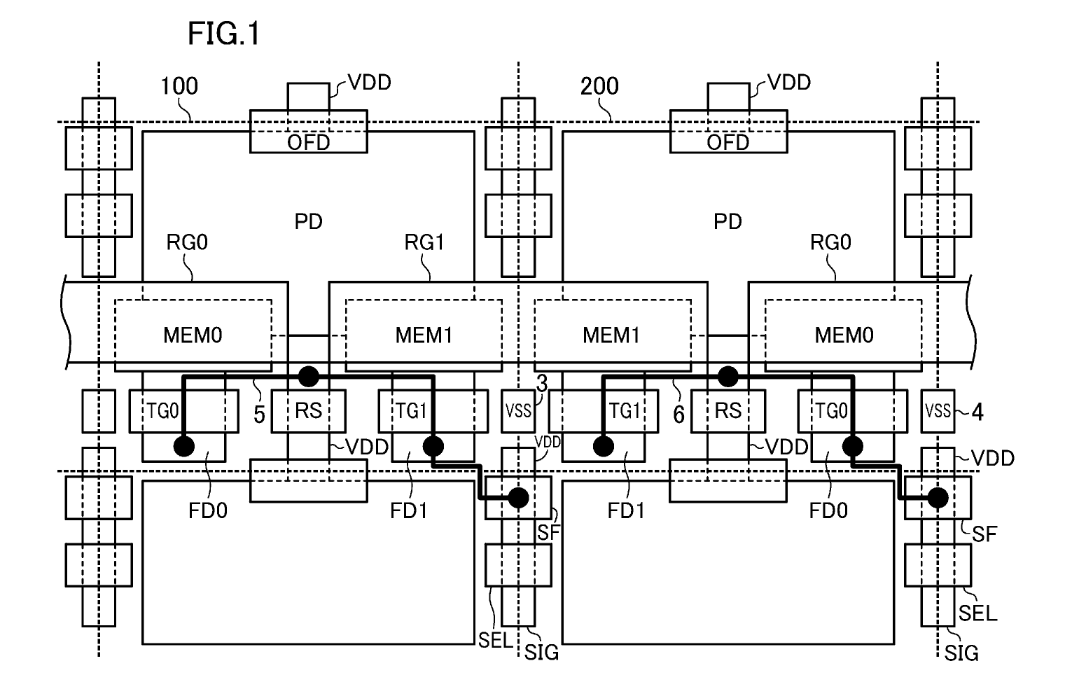

FIG. 1 is a plan view showing structures of two pixels adjacent to each other in a solid state imaging device according to a first embodiment of the present disclosure. The solid state imaging device shown in FIG. 1 includes a semiconductor substrate, a diffusion layer formed on the semiconductor substrate, various gates of a polysilicon layer formed on the diffusion layer, and a metal interconnect formed on the gates. The solid state imaging device includes a plurality of pixels, which are two-dimensionally arranged on the semiconductor substrate. FIG. 1 shows the entirety of two of these pixels (pixels 100 and 200) adjacent to each other in the row direction and portions of pixels surrounding the two pixels. The left pixel 100 and the right pixel 200 in FIG. 1 are hereinafter referred to as the “first pixel” and the “second pixel,” respectively.

The first pixel 100 includes a photodiode PD, first and second readout gates RG0 and RG1, first and second memories MEM0 and MEM1, an overflow drain OFD, first and second floating diffusion portions FD0 and FD1, first and second transfer gates TG0 and TG1, a reset transistor RS, a source follower (an amplifier transistor) SF, and a selection transistor SEL. The first and second floating diffusion portions FD0 and FD1, the drain of the reset transistor RS, and the gate of the source follower SF are connected together through a metal interconnect 5.

The photodiode PD is an element which is a rectangular diffusion layer as viewed in plan and which is used to generate charge by photoelectric conversion. The first and second readout gates RG0 and RG1 are each a polysilicon layer, and are used to read charge from the photodiode PD. In this embodiment, the first and second readout gates RG0 and RG1 are formed on left and right portions of the lower side of the photodiode PD, respectively. The first memory MEM0 temporarily retains charge received from the photodiode PD through the first readout gate RG0. The second memory MEM1 temporarily retains charge received from the photodiode PD through the second readout gate RG1. The overflow drain OFD discharges a surplus of charge from the photodiode PD, and is interposed between the upper side of the photodiode PD and a power supply VDD.

The first and second floating diffusion portions FD0 and FD1 are adjacent to the first and second memories MEM0 and MEM1, respectively. The first transfer gate TG0 is a polysilicon layer, and is used to transfer charge from the first memory MEM0 to the first floating diffusion portion FD0. The second transfer gate TG1 is a polysilicon layer, and is used to transfer charge from the second memory MEM1 to the second floating diffusion portion FD1.

The reset transistor RS is used to reset charge accumulated in the first and second floating diffusion portions FD0 and FD1. The source follower SF is a transistor configured to output a voltage signal in response to the charge accumulated in the first and second floating diffusion portions FD0 and FD1. The selection transistor SEL is interposed between the source follower SF and a signal line SIG, and is used to select one of rows.

The second pixel 200 has a structure similar to that of the first pixel 100. In the second pixel 200, first and second floating diffusion portions FD0 and FD1, the drain of a reset transistor RS, and the gate of a source follower SF are connected together through a metal interconnect 6. However, first and second readout gates RG0 and RG1, first and second memories MEM0 and MEM1, first and second transfer gates TG0 and TG1, and first and second floating diffusion portions FD0 and FD1 of the second pixel 200 are arranged to each form a mirror image of an equivalent component of the first pixel 100.

As further shown in FIG. 1, the first and second pixels 100 and 200 adjacent to each other in the row direction share the second readout gate RG1. The first pixel 100 and a pixel adjacent to the first pixel 100 on the left side thereof in the row direction share the first readout gate RG0. Furthermore, the second pixel 200 and a pixel adjacent to the second pixel 200 on the right side thereof in the row direction share the first readout gate RG0.

The solid state imaging device shown in FIG. 1 further includes substrate contacts 3, 4 for fixing the potential of the semiconductor substrate at the ground VSS. These substrate contacts 3, 4 are each disposed near one of the first and second readout gates RG0, RG1 shared by two adjacent ones of the pixels.

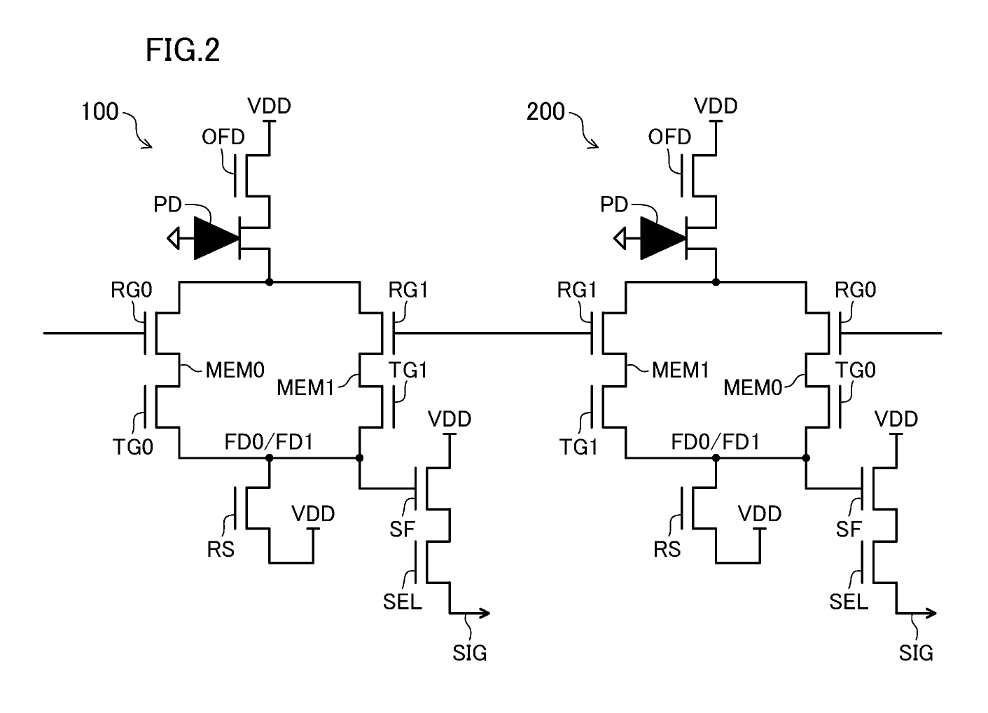

FIG. 2 is a circuit diagram of the first and second pixels 100 and 200 of the solid state imaging device shown in FIG. 1. In the first pixel 100, the photodiode PD is connected to the power supply VDD through the overflow drain OFD. The photodiode PD is connected to the first memory MEM0 through the first readout gate RG0, and is connected to the second memory MEM1 through the second readout gate RG1. The first and second memories MEM0 and MEM1 are connected to the first and second floating diffusion portions FD0 and FD1 through the first and second transfer gates TG0 and TG1, respectively. In this embodiment, the first and second floating diffusion portions FD0 and FD1 are connected together through the metal interconnect 5 as described above, and are thus shown in FIG. 2 as a single floating diffusion portion FD0/FD1. This floating diffusion portion FD0/FD1 is connected to the power supply VDD through the reset transistor RS, and is connected also to the gate of the source follower SF. The source follower SF is a transistor interposed between the power supply VDD and the selection transistor SEL. The selection transistor SEL is interposed between the source follower SF and the signal line SIG. The second pixel 200 has a circuit configuration similar to that of the first pixel 100. In addition, the first and second pixels 100 and 200 share the second readout gate RG1.

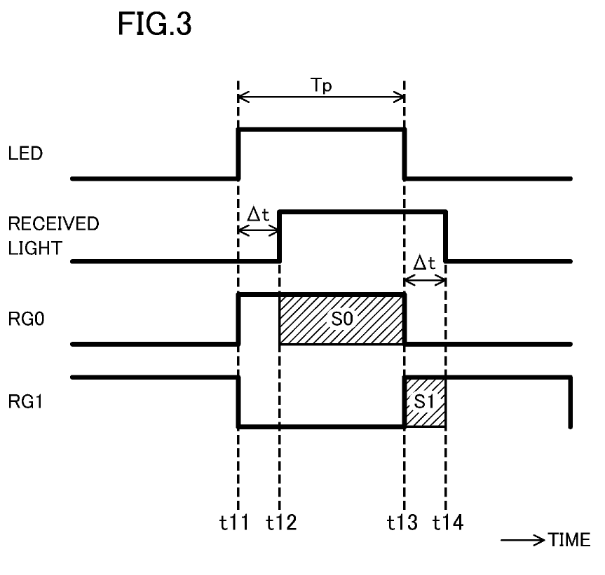

FIG. 3 is a timing diagram for explaining the principal of how the solid state imaging device shown in FIG. 1 measures the distance to an object. In this embodiment, L is the distance from an LED to an object to which pulsed light is emitted from the LED, and Tp is the period of time during which the LED is in an on state, i.e., the period of time from a time t11 to a time t13. The light emitted travels over the distance 2L at a speed c (=3.0×108 m/s) before returning to the solid state imaging device by being reflected off the object. Thus, the following formula (1) holds.

L=c×(Δt/2) (1)

where Δt is a delay period of time of received light with respect to the light emitted. A pulse of the received light rises at the time t12 at which the period of time At elapses since the time t11, and falls at the time t14 at which the period of time Δt elapses since the time t13. Thus, the photodiode PD generates charge by photoelectric conversion only from the time t12 to the time t14.

Meanwhile, the first readout gate RG0 is opened only during the period of time Tp from the time t11 to the time t13, and the second readout gate RG1 only during a period of time starting from the time t13 and being equal to the period of time Tp. In this case, the following relation holds.

Δt/Tp=S1/(S0+S1) (2)

where S0 is the amount of charge read via the first readout gate RG0 to the first memory MEM0, and S1 is the amount of charge read via the second readout gate RG1 to the second memory MEM1. The following formula holds based on the formulae (1) and (2).

L=(c×Tp)/2×S1/(S0+S1) (3)

That is to say, the distance L to the object can be determined based on the amounts S0 and S1 of charge distributed to the first and second memories MEM0 and MEM1.

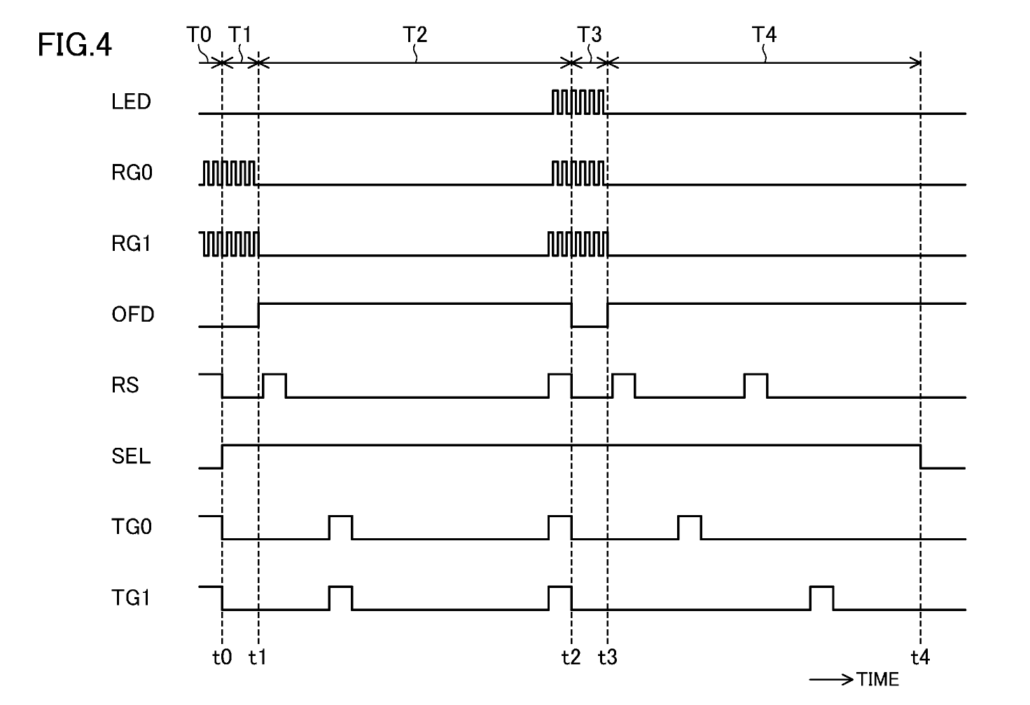

FIG. 4 is a timing diagram for explaining how the solid state imaging device shown in FIG. 1 operates. A period of time to a time t0 is a reset period of time T0, a period of time from the time t0 to a time t1 is a background light accumulation period of time T1, a period of time from the time t1 to a time t2 is a background light reading period of time T2, a period of time from the time t2 to a time t3 is a signal accumulation period of time T3, and a period of time from the time t3 to a time t4 is a signal reading period of time T4.

During the reset period of time T0, the overflow drain OFD is off, the reset transistor RS is on, and the first and second transfer gates TG0 and TG1 are on. The LED is not in the on state. The first and second readout gates RG0 and RG1 are alternately driven by pulses. During this period of time, the charge generated in the photodiode PD flows to the first and second memories MEM0 and MEM1. However, since the first and second transfer gates TG0 and TG1 are on, the charge flows through the reset transistor RS to the power supply VDD without being accumulated in the first and second memories MEM0 and MEM1.

Next, at the time t0, the reset transistor RS and the first and second transfer gates TG0 and TG1 are all turned off. From this time, the background light accumulation period of time T1 starts. During the background light accumulation period of time T1, an image that is not illuminated with the LED is photoelectrically converted by the photodiode PD. During this period of time, since the first and second readout gates RG0 and RG1 are alternately driven by pulses, the same amount of charge as a function of the background light is accumulated in each of the first and second memories MEM0 and MEM1. That is to say, the amount of charge accumulated in each of the first and second memories MEM0 and MEM1 is Q/2, where Q is the total amount of charge accumulated, as a function of the background light, in the first and second memories MEM0 and MEM1.

Next, at the time t1, the first and second readout gates RG0 and RG1 stop being driven by pulses, and the overflow drain OFD is turned on. From this time, the background light reading period of time T2 starts. During the background light reading period of time T2, new charge generated in the photodiode PD is discharged to the power supply VDD through the overflow drain OFD. The charge accumulated in the first and second memories MEM0 and MEM1 turns on the associated selection transistor SEL on a row-by-row basis. A reset potential is stored after a reset operation performed by turning on the reset transistor RS. Next, the first and second transfer gates TG0 and TG1 are turned on at the same time so that charge in each of the first and second memories MEM0 and MEM1 is transferred to the floating diffusion portion FD0/FD1. After the first and second transfer gates TG0 and TG1 have been turned off, a signal level is stored, and the difference between a reset level and the signal level is output. The output thus obtained is a value corresponding to the total charge amount Q described above.

Next, the reset transistor RS is turned on, the first and second transfer gates TG0 and TG1 are turned on, the LED is blinked, and the first and second readout gates RG0 and RG1 are alternately driven by pulses. At this time, charge generated in the photodiode PD flows to the first and second memories MEM0 and MEM1. However, since the first and second transfer gates TG0 and TG1 are on, the charge flows through the reset transistor RS to the power supply VDD without being accumulated in the first and second memories MEM0 and MEM1.

Next, at the time t2, the reset transistor RS and the first and second transfer gates TG0 and TG1 are all turned off. From this time, the signal accumulation period of time T3 starts. During the signal accumulation period of time T3, the LED blinks. The reflected LED light is photoelectrically converted by the photodiode PD. During this period of time, since the first and second readout gates RG0 and RG1 are alternately driven by pulses, the charge generated in the photodiode PD is distributed to the first and second memories MEM0 and MEM1 in accordance with the length of the delay period of time At described above. This charge distribution operation is preferably repeated multiple times. Consequently, signal charge is accumulated in each of the first and second memories MEM0 and MEM1. However, the signal charge thus obtained reflects the influence of the background light described above. Specifically, at this moment, the amount of charge accumulated in the first memory MEM0 is represented by Q/2+S0, and the amount of charge accumulated in the second memory MEM1 is represented by Q/2+S1, where S0 and S1 represent the charge amounts S0 and S1 that have been described with reference to FIG. 3.

Next, at the time t3, the first and second readout gates RG0 and RG1 stop being driven by pulses, and the overflow drain OFD is turned on. From this time, the signal reading period of time T4 starts. During the signal reading period of time T4, new charge generated in the photodiode PD is discharged to the power supply VDD through the overflow drain OFD. The charge accumulated in the first and second memories MEM0 and MEM1 turns on the selection transistor SEL on a row-by-row basis. A reset potential is stored after a reset operation performed by turning on the reset transistor RS. Next, the first transfer gate TG0 is turned on so that charge in the first memory MEM0 is transferred to the floating diffusion portion FD0/FD1. After the first transfer gate TG0 has been turned off, a signal level is stored, and the difference between a reset level and the signal level is output. This operation is similarly performed also for the second memory MEM1. The output thus obtained for the first memory MEM0 is a value corresponding to Q/2+S0. The output thus obtained for the second memory MEM1 is a value corresponding to Q/2+S1.

If the influence of the background light is removed based on the value corresponding to the total charge amount Q during the background light reading period of time T2 and the values respectively corresponding to Q/2+S0 and Q/2+S1 during the signal reading period of time T4, the signal charges S0 and S1 shown in FIG. 3 and distributed between the first and second memories MEM0 and MEM1 can be determined. Thus, the distance L to the object can be determined based on the formula (3).

If two adjacent ones of pixels do not share a readout gate, the distance between memories of the two adjacent pixels needs to be long enough so that the region therebetween includes “regions where readout gates of the two adjacent pixels overlap with memory diffusion layers thereof, respectively,” and “an isolation region between the memory diffusion layers.” By contrast, according to this embodiment in which two adjacent ones of the pixels share the readout gate, the distance between the memories of the two adjacent pixels merely needs to be long enough so that the region therebetween includes “an isolation region between memory diffusion layers of the two adjacent pixels.” Thus, according to this embodiment, the pixel pitch can be reduced without sacrificing the area of each photodiode PD and the area of each memory MEM0, MEM1.

According to this embodiment, the first readout gate RG0, the first memory MEM0, the first transfer gate TG0, and the first floating diffusion portion FD0 of the pixel 100 are arranged to respectively form a mirror image of the second readout gate RG1, the second memory MEM1, the second transfer gate TG1, and the second floating diffusion portion FD1 of the pixel 200 adjacent to the pixel 100 in the row direction. That is to say, when charge is read into the first memory MEM0 located on a left portion of the lower side of the photodiode PD in the first pixel 100, charge is read into the first memory MEM0 located on a right portion of the lower side of the photodiode PD in the second pixel 200. Conversely, when charge is read into the second memory MEM1 located on the right portion of the lower side of the photodiode PD in the first pixel 100, charge is read into the second memory MEM1 located on the left portion of the lower side of the photodiode PD in the second pixel 200. Whether charge is read from the photodiode PD into the memory MEM0 or MEM1 varies among columns as described above. Thus, the difference in characteristics between the memories MEM0 and MEM1 can be corrected based on output information on an adjacent column.

The substrate contacts 3 are each disposed near an associated one of the second readout gates RG1, and the substrate contacts 4 are each disposed near an associated one of the first readout gates RG0. The first and second readout gates RG0, RG1 are each shared by an associated adjacent pair of the pixels. Thus, the potential of the semiconductor substrate, which is made unstable by turning the first and second readout gates RG0, RG1 on or off, can be fixed at the ground VSS with low resistance. In addition, a crosstalk, i.e., connection between the first and second memories MEM0 and MEM1 under the isolation region, can be prevented before it occurs.

In this embodiment, it has been described that while the LED is blinking, charge generated by photoelectric conversion is distributed between the first and second memories MEM0 and MEM1. However, this is merely an example of the present disclosure. For example, the first and second readout gates RG0 and RG1 and the overflow drain OFD may be driven by pulses, and charge generated during a period of time except the period of time during which the solid state imaging device seems to receive reflected waves from the object may be discharged from the overflow drain OFD.

It has also been described, as an example, that to obtain background light information in a situation where the LED is not in the on state, the background light information and signal information are transferred through different frames. However, a target row may be changed, and signal charges in the first and second memories MEM0 and MEM1 associated with the target row changed may be read at the same time.

### Second Embodiment

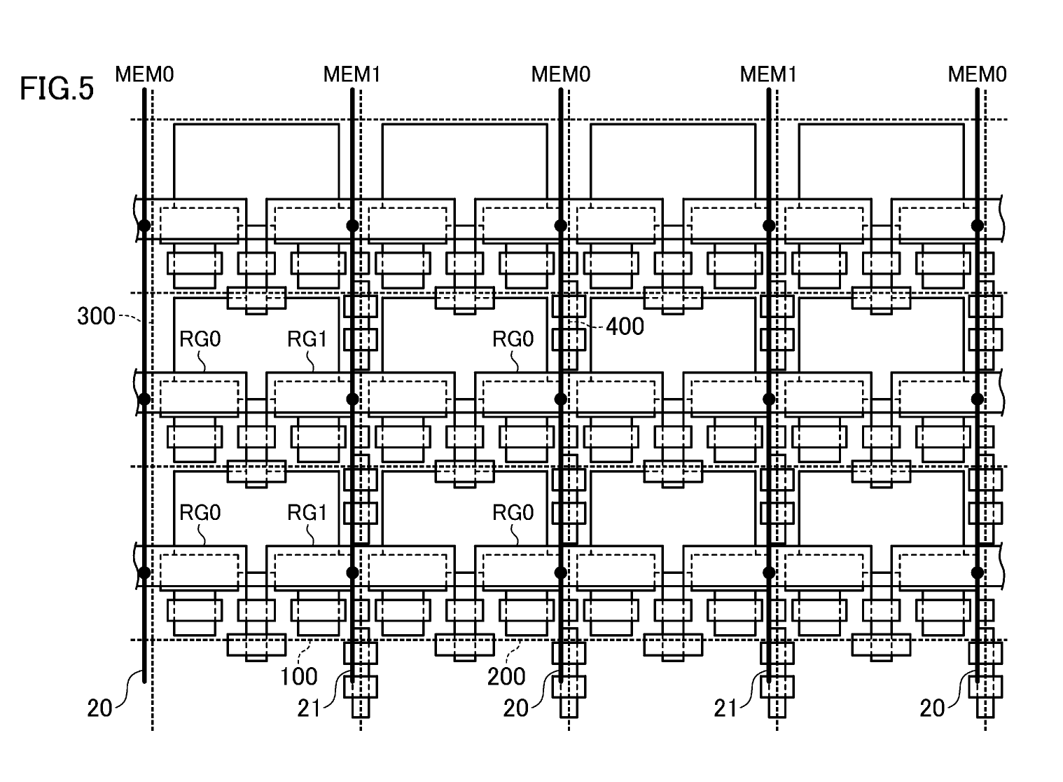

FIG. 5 is a plan view of a solid state imaging device according to a second embodiment of the present disclosure. FIG. 5 shows many pixels including, in addition to the first and second pixels 100 and 200 shown in FIG. 1, third and fourth pixels 300 and 400 adjacent to the first and second pixels 100 and 200 in the column direction, and further shows first and second readout gate control interconnects 20, 21, which are metal interconnects extending in a straight line along the column direction.

The first and second pixels 100 and 200 adjacent to each other in the row direction share the second readout gate RG1. The first pixel 100 and a pixel adjacent to the first pixel 100 on the left side thereof in the row direction share the first readout gate RG0. The first and second readout gates RG0 and RG1 are connected to the associated first and second readout gate control interconnects 20 and 21, respectively.

Likewise, the third and fourth pixels 300 and 400 adjacent to each other in the row direction share a second readout gate RG1. The third pixel 300 and a pixel adjacent to the third pixel 300 on the left side thereof in the row direction share a first readout gate RG0. Also for this row, the first and second readout gates RG0 and RG1 are connected to the associated first and second readout gate control interconnects 20 and 21, respectively.

Specifically, the first and third pixels 100 and 300 adjacent to each other in the column direction share both of the associated first and second readout gate control interconnects 20 and 21. The second and fourth pixels 200 and 400 adjacent to each other in the column direction also share both of the associated first and second readout gate control interconnects 20 and 21.

According to this embodiment, two pixels adjacent to each other in the row direction share one readout gate control interconnect. This can enlarge an opening of a photodiode PD of each pixel, and can provide high sensitivity.

As can be seen from the foregoing description, the solid state imaging device according to an embodiment of the present disclosure is useful as a solid state imaging device which can have a smaller pixel pitch while being kept capable of handling a sufficiently large charge amount generated by photoelectric conversion, and which can be used for distance measurement.

1. A solid state imaging device comprising
a plurality of pixels which are two-dimensionally arranged on a semiconductor substrate,
each of the pixels including:
a photodiode generating charge by photoelectric conversion;
two readout gates each reading charge from the photodiode; and
two memories each receiving the charge from the photodiode through an associated one of the two readout gates and temporarily retaining the charge received, wherein
one of the two readout gates of one of the pixels is connected through a gate interconnect to one of the two readout gates of another one of the pixels adjacent to the one of the pixels in a row direction.

2. The device of claim 1, wherein
the two readout gates are each a polysilicon layer.

3. The device of claim 1, wherein
each of the pixels further includes:
two floating diffusion portions adjacent to the two memories, respectively;
two transfer gates each transferring the charge from an associated one of the two memories to an associated one of the two floating diffusion portions; and
an amplifier transistor connected to the two floating diffusion portions in common.

4. The device of claim 3, wherein
the two transfer gates are each a polysilicon layer.

5. The device of claim 1, further comprising
a substrate contact fixing a potential of the semiconductor substrate, wherein
the substrate contact is close to the readout gate shared by the two pixels adjacent to each other.

6. The device of claim 1, further comprising
a readout gate control interconnect connected to the readout gate shared by the two pixels adjacent to each other, wherein
some of the pixels adjacent to one another in a column direction share the readout gate control interconnect, which is a metal interconnect extending in the column direction.

7. (canceled)
